(19) United States
(12) Patent Application Publication
(10) Pub. No.: US 2023/0065925 A1
(43) Pub. Date: Mar. 2, 2023

(54) SEMICONDUCTOR DEVICE AND METHOD OF MANUFACTURING THE SAME

(71) Applicant: Renesas Electronics Corporation., Tokyo (JP)

(72) Inventors: Makoto KOSHIMIZU, Tokyo (JP); Yasutaka NAKASHIBA, Tokyo (JP); Tohru KAWAI, Tokyo (JP)

(73) Assignee: Renesas Electronics Corporation., Tokyo (JP)

(21) Appl. No.: 17/867,768

(22) Filed: Jul. 19, 2022

(30) Foreign Application Priority Data
Aug. 25, 2021 (JP) 2021-137257

(51) Int. Cl. H01L 29/78; H01L 29/06; H01L 29/08

(52) U.S. Cl. CPC H01L 29/7816; H01L 29/0696; H01L 29/0878

(57) ABSTRACT

A semiconductor substrate has a surface and a convex portion projecting upward from the surface. An n-type drift region has a portion located in the convex portion. The n⁻-type drain region has a higher n-type impurity concentration than the n-type drift region, and is arranged in the convex portion and on the n-type drift region such that the n⁻-type drain region and a gate electrode sandwich the n-type drift region in plan view.

### CROSS-REFERENCE TO RELATED APPLICATIONS

The subject application claims priority to Japanese Patent Application No. 2021-137257, filed on Aug. 25, 2021. The disclosure of Japanese Patent Application No. 2021-137257 including the specification, drawings and abstract is incorporated herein by reference in its entirety.

### BACKGROUND

The present invention relates to a semiconductor device and a method of manufacturing the semiconductor device.

There are disclosed techniques listed below. [Non-Patent Document 1] Lin Wei et al., “A Novel Contact Field Plate Application in Drain-Extended-MOSFET Transistors”, Proceedings of The 29th International Symposium on Power Semiconductor Devices & ICs, Sapporo.

Non-Patent Document 1 discloses a conventional planar LDMOS (Laterally Diffused Metal Oxide Semiconductor) transistor having a relatively low breakdown voltage. In the configuration disclosed in Non-Patent Document 1, a p-type well region and an n⁻-type drift region are sandwiched between an n⁺-type source region and an n⁺-type drain region. This MOS transistor has a simple configuration in which no oxide film such as LOCOS (LOCal Oxidation of Silicon) or STI (Shallow Trench Isolation) is formed in the n⁻-type drift region.

### SUMMARY

With the above-described LDMOS transistor, it is difficult to achieve miniaturization while maintaining the breakdown voltage. In addition, it is difficult to achieve a high breakdown voltage while maintaining the same size.

Other issues and novel features will become apparent from the description in the present specification and accompanying drawings.

According to a semiconductor device of one embodiment, a semiconductor substrate has a surface and a convex portion projecting upward from the surface. A first region of a first conductivity type has a portion located in the convex portion. A drain region of the first conductivity type has a higher impurity concentration than the first region and is arranged in the convex portion and on the first region such that the drain region and a gate electrode sandwich the first region in plan view.

According to a semiconductor device of another embodiment, a semiconductor substrate has a surface, and a first convex portion and a second convex portion projecting upward from the surface. A first transistor has a first source region arranged in the surface, and a first drain region arranged in the first convex portion. A second transistor has a second source region and a second drain region arranged in the second convex portion.

According to a method of manufacturing a semiconductor device of one embodiment, a semiconductor substrate having a surface, a convex portion projecting upward from the surface, and a first region of a first conductivity type arranged in the convex portion is formed. A gate electrode is formed on the surface of the semiconductor substrate. A drain region of the first conductivity type is formed so as to have a higher impurity concentration than the first region and be arranged in the convex portion and on the first region such that the drain region and the gate electrode sandwich the first region in plan view.

According to the above-described embodiments, it is possible to realize a semiconductor device and a method of manufacturing the same that can easily improve breakdown voltage and achieve miniaturization of the semiconductor device.

### BRIEF DESCRIPTION OF THE DRAWINGS

FIG. 1 is a plan view of a configuration of a semiconductor device according to a first embodiment in a chip form.

FIG. 2 is a cross-sectional view of a configuration of the semiconductor device according to the first embodiment.

FIG. 3 is a cross-sectional view of a configuration of a modification example of the semiconductor device according to the first embodiment.

FIG. 4 is a cross-sectional view of the semiconductor device according to the first embodiment in a first step of a manufacturing method.

FIG. 5 is a cross-sectional view of the semiconductor device according to the first embodiment in a second step of the manufacturing method.

FIG. 6 is a cross-sectional view of the semiconductor device according to the first embodiment in a third step of the manufacturing method.

FIG. 7 is a cross-sectional view of a configuration of a comparative example.

FIG. 8 is a graph showing a relationship between a breakdown voltage BVDS and an ON resistance Rsp.

FIG. 9 is a cross-sectional view of a configuration of the semiconductor device according to a second embodiment.

FIG. 10 is a cross-sectional view of the semiconductor device according to the second embodiment in a first step of a manufacturing method.

FIG. 11 is a cross-sectional view of the semiconductor device according to the second embodiment in a second step of the manufacturing method.

FIG. 12 is a cross-sectional view of the semiconductor device according to the second embodiment in a third step of the manufacturing method.

FIG. 13 is a cross-sectional view of the semiconductor device according to the second embodiment in a fourth step of the manufacturing method.

FIG. 14 is a cross-sectional view of a configuration of the semiconductor device according to a third embodiment.

FIG. 15 is a cross-sectional view of the semiconductor device according to the third embodiment in a first step of a manufacturing method.

FIG. 16 is a cross-sectional view of the semiconductor device according to the third embodiment in a second step of the manufacturing method.

FIG. 17 is a cross-sectional view of the semiconductor device according to the third embodiment in a third step of the manufacturing method.

FIG. 18 is a cross-sectional view of a configuration of an application example of the semiconductor device according to the first embodiment.

### DETAILED DESCRIPTION

Hereinafter, embodiments of the present invention will be described in detail with reference to the drawings. Note that, in the description and the drawings, the same components or corresponding components are denoted by the same reference sign, and redundant descriptions thereof are omitted as appropriate. Some components may be omitted from the drawings or may be simplified in the drawings for convenience of explanation. In addition, at least some portions in each embodiment and each modification example may be combined with each other as necessary.

Note that the semiconductor devices of the embodiments described below are not limited to semiconductor chips and may be semiconductor wafers before being divided into semiconductor chips, or may be semiconductor packages in which semiconductor chips are encapsulated in resin. In addition, “plan view” in the descriptions means a viewpoint viewed from a direction orthogonal to a surface of the semiconductor substrate.

### First Embodiment

<Configuration of Semiconductor Device in Chip Form>

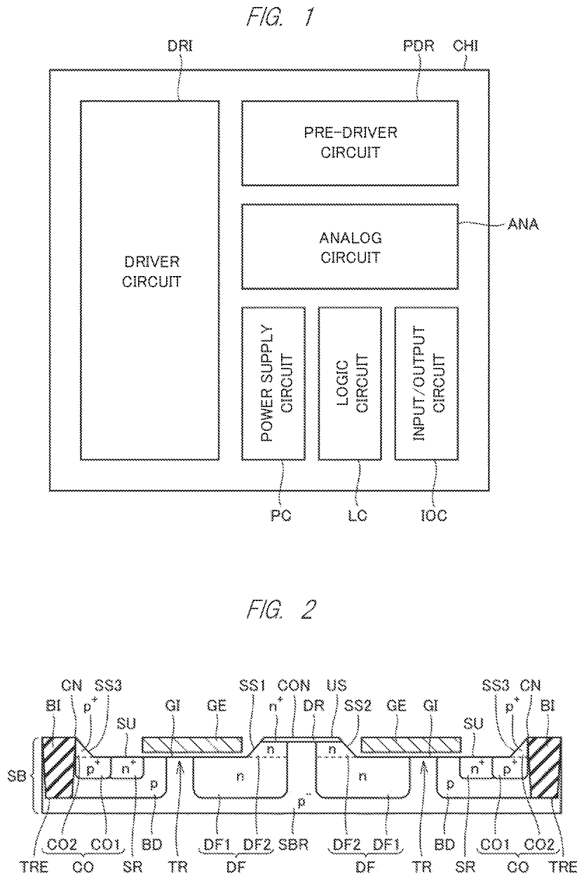

First, a configuration of a semiconductor device in a chip form according to a first embodiment will be described with reference to FIG. 1.

As shown in FIG. 1, the semiconductor device CHI according to the present embodiment is, for example, in the chip form and has a semiconductor substrate. Formation regions such as for a driver circuit DRI, a pre-driver circuit PDR, an analog circuit ANA, a power supply circuit PC, a logic circuit LC, and an input/output circuit IOC are each arranged on a surface of the semiconductor substrate.

For example, an LDMOS transistor is arranged on each of the driver circuit DRI and the power supply circuit PC.

<Configuration Of LDMOS Transistor>

Next, a configuration of the LDMOS transistor used in the semiconductor device CHI of FIG. 1 will be described with reference to FIG. 2.

Note that, in the following, the LDMOS transistor using a silicon oxide film as a gate insulating layer will be described. However, the gate insulating layer is not limited to the silicon oxide film and may be any other insulating film. In other words, the transistor used in the present embodiment is not limited to the LDMOS transistor and may be an LDMIS (Laterally Diffused Metal Insulator Semiconductor) transistor.

As shown in FIG. 2, a semiconductor substrate SB has a surface SU, a convex portion CON, and a convex portion CN. The convex portion CON and the convex portion CN each project upward from the surface SU. In cross section, the convex portion CON has side surfaces SS1 and SS2, and an upper surface US. Each of the side surfaces SS1 and SS2 is an inclined surface that is inclined with respect to the surface SU of the semiconductor substrate SB. In cross section, the side surfaces SS1 and SS2 configure a tapered shape in which a lateral distance between the side surfaces SS1 and SS2 decreases from the bottom to the top.

The side surfaces SS1 and SS2 each have a crystal plane of {111}. The side surfaces SS1 and SS2 each have a crystal plane of, for example, (111), but are not limited to this and may have any crystal plane equivalent to (111). In addition, the surface SU of the semiconductor substrate SB has a crystal plane of, for example, (100), but is not limited to this and may have any crystal plane equivalent to (100).

The side surfaces SS1 and SS2 are each inclined at an angle of, for example, 54.7±2° (52.7° to 56.7°, inclusive) with respect to the surface SU of the semiconductor substrate SB. In a case where the surface of the semiconductor substrate SB has a crystal plane of, for example, (100) and the side surfaces SS1 and SS2 each have a crystal plane of, for example, (111), an angle between each of the side surfaces SS1, SS2 and the surface SU is theoretically 54.7°. However, in practice, due to manufacturing errors and the like, the angle between each of the side surfaces SS1, SS2 and the surface SU may vary within a range of ±2°.

The upper surface US is connected to an upper end of each of the side surfaces SS1 and SS2. The upper surface US is a flat surface and is substantially parallel to, for example, the surface SU of the semiconductor substrate SB. Thus, a cross-sectional shape of the convex portion CON is trapezoidal.

The convex portion CN has a similar cross-sectional shape as the convex portion CON. For this reason, a side surface SS3 of the convex portion CN is an inclined surface that is inclined with respect to the surface SU of the semiconductor substrate SB.

In addition, the side surface SS3 of the convex portion CN has a crystal plane of {111}.

In the semiconductor substrate SB, an STI (Shallow Trench Isolation) structure which is an element isolation structure is arranged so as to surround an active region in plan view. The STI structure has a trench TRE and an insulating layer BI. The trench TRE extends from the surface of the semiconductor substrate SB to a predetermined depth. The insulating layer BI fills the trench TRE. Impurity regions each configuring an LDMOS transistor TR are arranged in the active region surrounded by the STI structure.

The LDMOS transistor TR has a p-type body region BD, an n-type drift region DF (first region), an n⁺-type source region SR, an n⁺-type drain region DR, a gate insulating layer GI, and a gate electrode GE.

A p⁻-type substrate region SBR (second region) is arranged in the semiconductor substrate SB. The p-type body region BD is arranged in the semiconductor substrate SB and is in contact with the p⁻-type substrate region SBR. The p-type body region BD has a portion located in the surface SU of the semiconductor substrate SB. The p-type body region BD has a higher p-type impurity concentration than the p⁻-type substrate region SBR.

The n-type drift region DF is arranged in the semiconductor substrate SB and forms a pn junction with the p⁻-type substrate region SBR. The n-type drift region DF is located between the gate electrode GE and the n⁺-type drain region DR in plan view. The n-type drift region DF has a first semiconductor region DF1 and a second semiconductor region DF2. The first semiconductor region DF1 is located below the convex portion CON. The second semiconductor region DF2 is arranged on the first semiconductor region DF1 and is located in the convex portion CON.

The second semiconductor region DF2 extends upward from an upper end of the first semiconductor region DF1. The first semiconductor region DF1 has an n-type impurity concentration equal to that of the second semiconductor region DF2. The n-type impurity concentration of each of the first semiconductor region DF1 and the second semiconductor region DF2 is, for example, 1×10¹⁷/cm³. A boundary between the first semiconductor region DF1 and the second semiconductor region DF2 is, for example, a surface extended from the surface SU of the semiconductor substrate SB (dashed line in the drawings).

There may be a case where an organized discontinuity or oxide exists at the boundary between the first semiconductor region DF1 and the second semiconductor region DF2. In addition, there may be a case where the first semiconductor region DF1 and the second semiconductor region DF2 are formed integral to each other, and the boundary between the first semiconductor region DF1 and the second semiconductor region DF2 is not recognizable.

The n⁺-type source region SR is arranged in the surface SU of the semiconductor substrate SB. The n⁺-type source region SR forms a pn junction with the p-type body region BD.

The n⁺-type drain region DR is arranged in an upper end of the convex portion CON. The n⁺-type drain region DR is in contact with an upper end of the n-type drift region DF. The n-type drift region DF has a lower n-type impurity concentration than each of the n⁺-type source region SR and the n⁺-type drain region DR.

The p-type body region BD, the p⁻-type substrate region SBR and the n-type drift region DF are sandwiched between the n⁺-type source region SR and the n⁺-type drain region DR. In the surface SU of the semiconductor substrate SB, the p-type body region BD, the p⁻-type substrate region SBR and the n-type drift region DF are arranged in this order from the n⁺-type source region SR toward the n⁺-type drain region DR.

The second semiconductor region DF2 and the n⁺-type drain region DR of the n-type drift region DF are located in each of the side surfaces SS1 and SS2 of the convex portion CON. Specifically, the second semiconductor region DF2 of the n-type drift region DF is arranged in a lower portion of each of the side surfaces SS1 and SS2 of the convex portion CON. In addition, the n⁺-type drain region DR is arranged in an upper portion of each of the side surfaces SS1 and SS2 of the convex portion CON. For this reason, a junction between the second semiconductor region DF2 and the n⁺-type drain region DR is located in each of the side surfaces SS1 and SS2 of the convex portion CON.

The gate electrode GE is arranged on the surface SU of the semiconductor substrate SB. The gate electrode GE faces at least the p-type body region BD and the p⁻-type substrate region SBR with the gate insulating layer GI interposed therebetween. The gate electrode GE also faces the first semiconductor region DF1 with the gate insulating layer GI interposed therebetween. The gate electrode GE is made of, for example, an impurity-introduced polycrystalline silicon.

A p⁺-type contact region CO is arranged in the semiconductor substrate SB and is in contact with each of the n⁺-type source region SR and the p-type body region BD. The p⁺-type contact region CO has a higher p-type impurity concentration than the p-type body region BD.

The p⁺-type contact region CO has a first p⁺-type region CO1 and a second p⁺-type region CO2. The first p⁺-type region CO1 is located below the convex portion CN. The second p⁺-type region CO2 is arranged on the first p⁺-type region CO1 and is located in the convex portion CN.

The second p⁺-type region CO2 extends upward from an upper end of the first p⁺-type region CO1. The first p⁺-type region CO1 has a p-type impurity concentration equal to that of the second p⁺-type region CO2. A boundary between the first p⁺-type region CO1 and the second p+-type region CO2 is, for example, a surface extended from the surface SU of the semiconductor substrate SB (dashed line in the drawings).

There may be a case where an organized discontinuity or oxide exists at the boundary between the first p⁺-type region CO1 and the second p⁺-type region CO2. In addition, there may be a case where the first p⁺-type region CO1 and the second p⁺-type region CO2 are formed integral to each other, and the boundary between the first p⁺-type region CO1 and the second p⁺-type region CO2 is not recognizable.

In a region just below the convex portion CON, the p⁻-type substrate region SBR penetrates the first semiconductor region DF1 and the second semiconductor region DF2 and reaches the n⁺-type drain region DR. Thus, the p⁻-type substrate region SBR forms a pn junction with a side portion of each of the first semiconductor region DF1 and the second semiconductor region DF2 in the region just below the convex portion CON. Thus, the p⁻-type substrate region SBR is arranged in the convex portion CON and also forms a pn junction with the second semiconductor region DF2 in the convex portion CON. The p⁻-type substrate region SBR forming the pn junction with the first semiconductor region DF1 and the second semiconductor region DF2 makes it possible to achieve a RESURF effect.

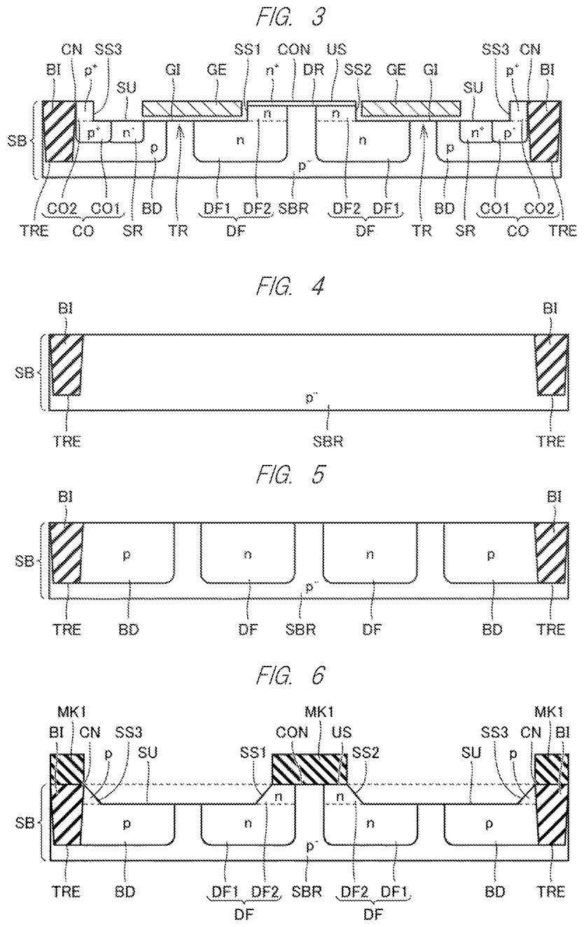

Note that the side surfaces SS1, SS2 and SS3 may each be arranged upright so as to be orthogonal to the surface SU of the semiconductor substrate SB, as shown in FIG. 3. In this case, the cross-sectional shape of each of the convex portions CON and CN is, for example, a rectangle or a square.

The side surfaces SS1, SS2 and SS3 of the convex portions CON and CN each have a crystal plane of {111}. The side surfaces SS1 and SS2 each have a crystal plane of, for example, (111), but are not limited to this and may have any crystal plane equivalent to (111). In addition, the surface SU of the semiconductor substrate SB has a crystal plane of, for example, (110), but is not limited to this and may have any crystal plane equivalent to (110).

The side surfaces SS1, SS2 and SS3 are each arranged upright at an angle of, for example, 90.0±2° (88.0° to 92.0°, inclusive) with respect to the surface SU of the semiconductor substrate SB. In a case where the surface of the semiconductor substrate SB has a crystal plane of, for example, (110) and the side surfaces SS1, SS2 and SS3 each have a crystal plane of, for example, (111), the angle between each of the side surfaces SS1, SS2, SS3 and the surface SU is theoretically 90.0°. However, in practice, due to manufacturing errors and the like, the angle between each of the side surfaces SS1, SS2 and the surface SU may vary within a range of ±2°.

Note that the configuration other than those described above in the modification example shown in FIG. 3 is substantially the same as that of FIG. 2. Therefore, the same elements are denoted by the same reference sign, and redundant descriptions thereof are omitted as appropriate.

<Method of Manufacturing the LDMOS Transistor>

Next, a manufacturing method of the LDMOS transistor in present embodiment shown in FIG. 2 will be described with reference to FIGS. 4 to 6.

As shown in FIG. 4, the STI structure is formed in the surface of the semiconductor substrate SB having the p⁻-type substrate region SBR. Specifically, the trench TRE is formed in the surface of the semiconductor substrate SB by a photolithography technique and an etching technique. The insulating layer BI made of, for example, a silicon oxide film is formed on the surface of the semiconductor substrate SB so as to fill the trench TRE. Subsequently, the insulating layer BI is removed by CMP (Chemical Mechanical Polishing) until the surface of the semiconductor substrate SB is exposed. Thus, the insulating layer BI remains in the trench TRE to form the STI structure.

Next, as shown in FIG. 5, an n-type well region DF and a p-type well region BD are formed in the semiconductor substrate SB. The n-type well region DF is the n-type drift region DF, and the p-type well region BD is the p-type body region BD. The n-type drift region DF is formed so as to form a pn junction with the p⁻-type substrate region SBR in the lower and side portions. The p-type body region BD is formed such that the lower and side portions are in contact with the p⁻-type substrate region SBR.

Next, as shown in FIG. 6, a mask layer MK1 made of, for example, a silicon oxide film is formed on the surface of the semiconductor substrate SB. Anisotropic wet etching using, for example, a TMAH (tetramethylammonium hydroxide) aqueous solution is performed with the mask layer MK1 serving as a mask. This etching allows the surface of the semiconductor substrate SB exposed from the mask layer MK1 to be selectively removed to a predetermined depth.

In this anisotropic wet etching, there is a large crystal orientation dependence, and in the case of silicon, an etching rate is fast in a <100> direction and is the slowest in a <111> direction. For this reason, performing anisotropic wet etching by using a silicon substrate with a (100) plane allows the convex portion CON having the side surfaces SS1 and SS2 with a (111) plane to be formed. Thus, the trapezoidal convex portion CON having the side surfaces SS1 and SS2 inclined with respect to the surface SU of the semiconductor substrate SB, and the upper surface US connecting each of the upper ends of the side surfaces SS1 and SS2 is formed. In addition, the convex portion CN having the side surface SS3 with a (111) plane is also formed by the above-described anisotropic wet etching.

The above-described etching makes it possible to distinguish between the first semiconductor region DF1 located below the convex portion CON and the second semiconductor region DF2 located in the convex portion CON with respect to the surface SU of the semiconductor substrate SB. In other words, the n-type drift region DF can be divided into the first semiconductor region DF1 located below the surface SU of the semiconductor substrate SB and the second semiconductor region DF2 located above the surface SU of the semiconductor substrate SB. Subsequently, the mask layer MK1 is removed.

Next, as shown in FIG. 2, the surface SU of the semiconductor substrate SB is oxidized. Thus, the gate insulating layer GI made of a silicon oxide film is formed so as to cover the surface SU of the semiconductor substrate SB and surfaces of the convex portions CON and CN.

Next, an impurity-introduced polycrystalline silicon layer GE is formed on the gate insulating layer GI. The polycrystalline silicon layer GE is patterned by the photolithography technique and the etching technique to form the gate electrode GE.

Subsequently, n-type impurities are ion-implanted or the like into the semiconductor substrate SB to form the n⁺-type source region SR and the n⁺-type drain region DR. The n⁺-type source region SR is formed in the surface SU of the semiconductor substrate SB. The n⁺-type source region SR is formed so as to form a pn junction with the p-type body region BD. The n⁺-type drain region DR is formed in the upper surface US of the convex portion CON. The n⁺-type drain region DR is formed so as to be in contact with the upper end of each of the second semiconductor region DF2 and the p⁻-type substrate region SBR.

In addition, p-type impurities are ion-implanted or the like into the semiconductor substrate SB to form the p⁺-type contact region CO in the semiconductor substrate SB. The p⁺-type contact region CO is formed such that a side portion is in contact with the n⁺-type source region SR and a lower portion is in contact with the p-type body region BD. The p⁺-type contact region CO makes it possible to distinguish between the first p⁺-type region CO1 located below the convex portion CN and the second p⁺-type region CO2 located in the convex portion CN. In other words, the p⁺-type contact region CO can be divided into the first p⁺-type region CO1 located below the surface SU of the semiconductor substrate SB and the second p⁺-type region CO2 located above the surface SU of the semiconductor substrate SB.

In the above-described manner, the LDMOS transistor TR of the present embodiment is formed.

Note that the configuration shown in FIG. 3 can be obtained by performing, in FIG. 6, anisotropic wet etching using the TMAH aqueous solution on the surface of the semiconductor substrate SB having a crystal plane of, for example, (110) with the mask layer MK1 serving as a mask. Other manufacturing steps are the same as those described above, and thus, redundant descriptions thereof are omitted as appropriate.

<Effects>

Next, effects of the present embodiment will be described.

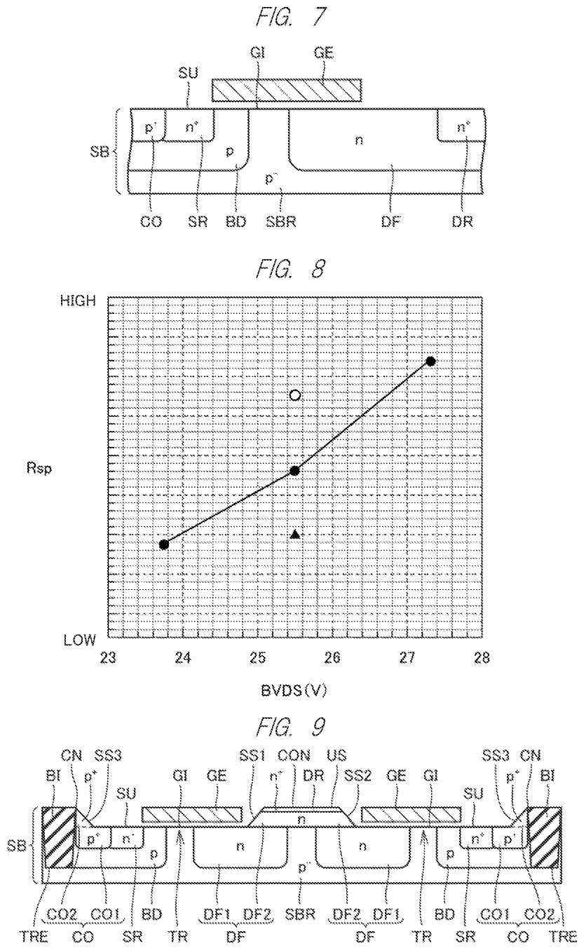

The present inventors investigated the relationship between a breakdown voltage BVDS and an ON resistance Rsp for each of the configurations of the present embodiment shown in FIGS. 2 and 3 and the comparative example shown in FIG. 7. The results obtained are shown in FIG. 8.

In the comparative example shown in FIG. 7, the surface SU of the semiconductor substrate SB is not provided with the convex portions CON and CN. In addition, the n⁺-type drain region DR is arranged in the surface SU of the semiconductor substrate SB. Note that the configuration other than those described above in the comparative example shown in FIG. 7 is substantially the same as that of the present embodiment shown in FIG. 2. Therefore, the same elements are denoted by the same reference sign, and redundant descriptions thereof are omitted as appropriate.

In FIG. 8, data denoted by a white circle is data of the comparative example shown in FIG. 7, data denoted by black circles are data of the present embodiment shown in FIG. 2, and data denoted by a black triangle is data of the present embodiment shown in FIG. 3.

The results in FIG. 8 show that, in a relatively low breakdown voltage BVDS range of 23V to 28V, the configuration of the present embodiment shown in FIG. 2 shows a decrease in the ON resistance Rsp with respect to the configuration of the comparative example shown in FIG. 7 when the breakdown voltages BVDS are the same.

In addition, in the relatively low breakdown voltage BVDS range of 23V to 28V, the configuration of the present embodiment shown in FIG. 3 shows a further decrease in the ON resistance Rsp with respect to the configuration of the present embodiment shown in FIG. 2 when the breakdown voltages BVDS are the same.

In addition, the configuration of the present embodiment shown in FIG. 2 shows an improvement in the breakdown voltage BVDS with respect to the configuration of the comparative example shown in FIG. 7 when the ON resistances Rsp are the same. In addition, the configuration of the present embodiment shown in FIG. 3 shows a further improvement in the breakdown voltage BVDS with respect to the configuration of the present embodiment shown in FIG. 2 when the ON resistances Rsp are the same.

From the above, according to the present embodiment shown in FIGS. 2 and 3, a higher breakdown voltage can be obtained when the size of the LDMOS transistor is the same with respect to the comparative example shown in FIG. 7. This is considered to be based on the fact that, in the present embodiment, the n⁺-type drain region DR is arranged in the upper surface US of the convex portion CON as shown in FIGS. 2 and 3. In other words, the n⁺-type drain region DR arranged in the upper surface US of the convex portion CON allows a current path length between the n⁺-type source region SR and the n⁺-type drain region DR to be increased to the extent that the side surfaces SS1 and SS2 of the convex portion CON are inclined or are arranged upright, and thus, it is considered that the breakdown voltage can be improved.

In addition, according to the present embodiment shown in FIGS. 2 and 3, a cell size of the LDMOS transistor TR can be reduced when the breakdown voltage is the same with respect to the comparative example shown in FIG. 7.

From the above, the LDMOS transistor TR of the present embodiment shown in FIGS. 2 and 3 can be easily improved in breakdown voltage and can be easily miniaturized with respect to the comparative example shown in FIG. 7.

In addition, according to the present embodiment shown in FIG. 3, a higher breakdown voltage can be obtained when the size of the LDMOS transistor is the same with respect to the present embodiment shown in FIG. 2. This is considered to be based on the fact that, in the present embodiment, the side surfaces SS1 and SS2 of the convex portion CON are arranged upright with respect to the surface SU of the semiconductor substrate SB as shown in FIG. 3. In other words, the side surfaces SS1 and SS2 of the convex portion CON arranged upright with respect to the surface SU allows the current path length between the n⁺-type source region SR and the n+-type drain region DR to be longer than the current path length in the case where the side surfaces SS1 and SS2 of the convex portion CON are inclined (FIG. 2), and thus, it is considered that the breakdown voltage can be improved.

In addition, according to the present embodiment shown in FIG. 3, the cell size of the LDMOS transistor TR can be reduced when the breakdown voltage is the same with respect to the present embodiment shown in FIG. 2.

From the above, the LDMOS transistor TR of the present embodiment shown in FIG. 3 can be easily improved in breakdown voltage and can be easily miniaturized with respect to the present embodiment shown in FIG. 2.

In addition, according to the present embodiment, the p⁻-type substrate region SBR is adjacent to each of the first semiconductor region DF1 and the second semiconductor region DF2 as shown in FIGS. 2 and 3. Thus, the RESURF effect can be obtained in the first semiconductor region DF1 and the second semiconductor region DF2.

In addition, according to the present embodiment, the p⁻-type substrate region SBR has a portion arranged in the convex portion CON as shown in FIGS. 2 and 3. Thus, the p⁻-type substrate region SBR can form a pn junction with the side portion of the second semiconductor region DF2 arranged in the convex portion CON. For this reason, the RESURF effect can also be obtained in the second semiconductor region DF2 in the convex portion CON.

In addition, according to the present embodiment, the p⁻-type substrate region SBR is electrically connected to a ground potential as shown in FIGS. 2 and 3. Thus, the RESURF effect can be obtained by the p⁻-type substrate region SBR.

In addition, according to the present embodiment, the side surfaces SS1 and SS2 of the convex portion CON are each configured by an inclined surface having a {111} plane as shown in FIGS. 2 and 3. Thus, an inclined or upright surface can be easily formed by anisotropic wet etching using the TMAH aqueous solution.

### Second Embodiment

<Configuration of LDMOS Transistor>

Next, a configuration of the LDMOS transistor as the semiconductor device according to a second embodiment will be described with reference to FIG. 9.

As shown in FIG. 9, the LDMOS transistor TR of the present embodiment differs from the configuration of the first embodiment shown in FIG. 2 in that the p⁻-type substrate region SBR is not arranged in the convex portion CON.

The n-type second semiconductor region DF2 and the n⁺-type drain region DR are arranged in the convex portion CON. The n-type second semiconductor region DF2 is arranged in the entire lower portion of the convex portion CON. In addition, the n⁺-type drain region DR is arranged in the entire upper portion of the convex portion CON. The p⁻-type substrate region SBR forms a pn junction with a lower end of the second semiconductor region DF2. The pn junction formed by the p⁻-type substrate region SBR and the second semiconductor region DF2 extends along a line extended from the surface SU of the semiconductor substrate SB.

Note that the configuration other than those described above in the present embodiment is substantially the same as that of the first embodiment. Therefore, the same elements are denoted by the same reference sign, and redundant descriptions thereof are omitted as appropriate.

<Method Of Manufacturing The LDMOS Transistor>

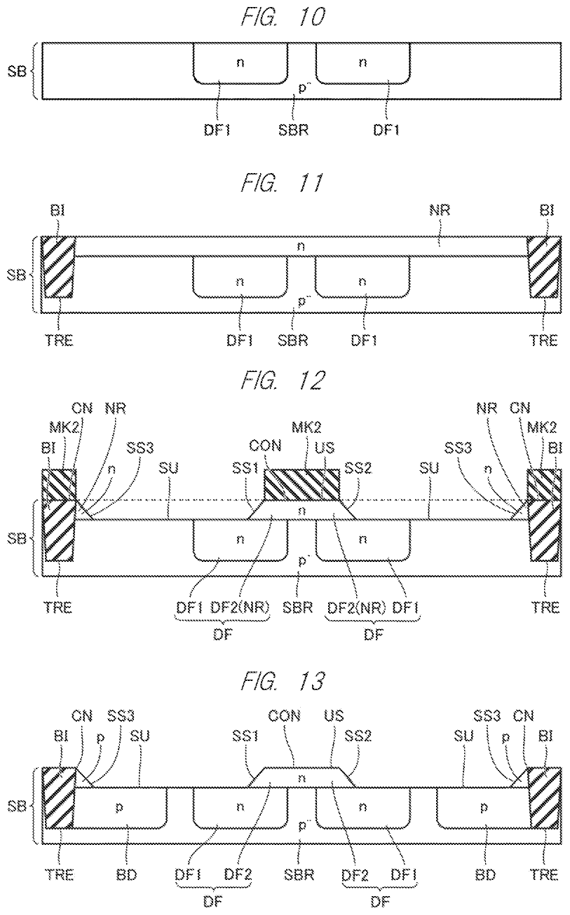

Next, the manufacturing method of the LDMOS transistor as the semiconductor device according to the present embodiment will be described with reference to FIGS. 10 to 14.

As shown in FIG. 10, according to the manufacturing method of the present embodiment, first, an n-type diffusion region DF1 is selectively formed on the surface of the semiconductor substrate SB having the p⁻-type substrate region SBR. The n-type diffusion region DF1 is formed so as to form a pn junction with the p⁻-type substrate region SBR at the side portion and the lower portion. The n-type diffusion region DF1 is the first semiconductor region DF1 of the n-type drift region DF.

Next, as shown in FIG. 11, an n-type epitaxial layer NR is formed on the surface of the semiconductor substrate SB by an epitaxial growth method. Subsequently, the STI structure is formed in the surface of the semiconductor substrate SB. Specifically, the trench TRE is formed in the surface of the semiconductor substrate SB by the photolithography technique and the etching technique. The insulating layer BI made of, for example, a silicon oxide film is formed on the surface of the semiconductor substrate SB so as to fill the trench TRE. Subsequently, the insulating layer BI is removed by CMP until the surface of the semiconductor substrate SB is exposed. Thus, the insulating layer BI remains in the trench TRE to form the STI structure.

Next, as shown in FIG. 12, a mask layer MK2 made of, for example, a silicon oxide film is formed on the surface of the semiconductor substrate SB. Anisotropic wet etching using, for example, the TMAH aqueous solution is performed with the mask layer MK2 serving as a mask. This etching is performed until at least the p⁻-type substrate region SBR is exposed. Thus, the n-type epitaxial layer NR exposed from the mask layer MK2 is selectively removed.

In this anisotropic wet etching, there is a large crystal orientation dependence, and in the case of silicon, the etching rate is fast in the <100> direction and is the slowest in the <111> direction. For this reason, performing anisotropic wet etching by using a silicon substrate with a (100) plane allows the convex portion CON having the side surfaces SS1 and SS2 with a (111) plane to be formed. Thus, the trapezoidal convex portion CON having the side surfaces SS1 and SS2 inclined with respect to the surface SU of the semiconductor substrate SB, and the upper surface US connecting each of the upper ends of the side surfaces SS1 and SS2 is formed. In addition, the convex portion CN having the side surface SS3 with a (111) plane is also formed by the above-described anisotropic wet etching.

The above-described etching makes it possible to distinguish between the first semiconductor region DF1 located below the convex portion CON and the second semiconductor region DF2 located in the convex portion CON with respect to the surface SU of the semiconductor substrate SB. In other words, the n-type drift region DF can be divided into the first semiconductor region DF1 located below the surface SU of the semiconductor substrate SB and the second semiconductor region DF2 located above the surface SU of the semiconductor substrate SB. Subsequently, the mask layer MK2 is removed.

Next, as shown in FIG. 13, a p-type diffusion region BD is selectively formed in the surface of the semiconductor substrate SB. The p-type diffusion region BD is the p-type body region. When forming the p-type diffusion region BD, p-type impurities are selectively ion-implanted into the semiconductor substrate

SB. At this time, p-type impurities are also implanted into the convex portion CN. For this reason, a p-type diffusion region is also formed in a region of the convex portion CN where the STI structure is not formed.

Subsequently, the manufacturing method of the present embodiment undergoes the same steps as the manufacturing method of the first embodiment. Thus, the LDMOS transistor TR of the present embodiment shown in FIG. 9 is formed.

### Third Embodiment

### <Configuration of LDMOS Transistor>

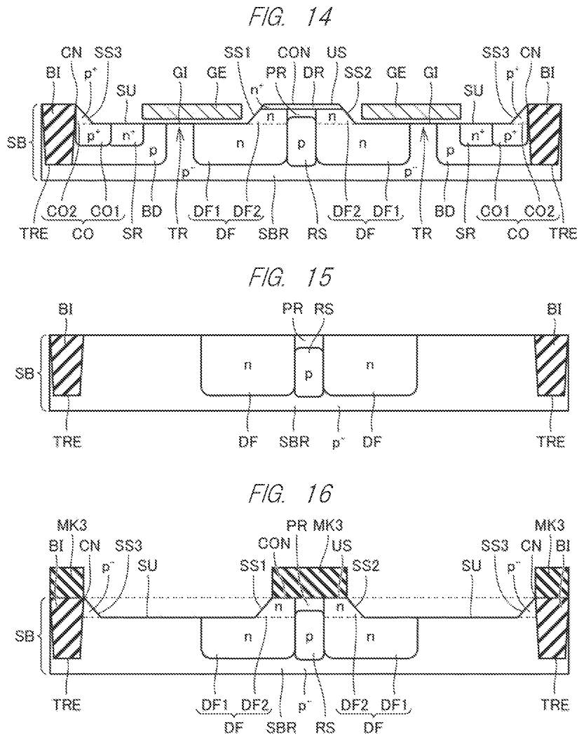

Next, a configuration of the LDMOS transistor as the semiconductor device according to a third embodiment will be described with reference to FIG. 14.

As shown in FIG. 14, the LDMOS transistor TR of the present embodiment differs from the configuration of the first embodiment shown in FIG. 2 in that a p-type RESURF region RS is added. The p-type RESURF region RS has a higher p-type impurity concentration than the p⁻-type substrate region SBR. The p-type RESURF region RS forms a pn junction with the side portion of each of the first semiconductor region DF1 and the second semiconductor region DF2 in a region just below the convex portion CON.

The p-type RESURF region RS extends to a position higher than the surface SU of the semiconductor substrate SB. In other words, the p-type RESURF region RS has a portion located below the convex portion CON and a portion located in the convex portion CON.

The p-type RESURF region RS is arranged in a region just below the n⁺-type drain region DR and away from the n⁺-type drain region DR. A p⁻-type region PR is arranged between the p-type RESURF region RS and the n⁺-type drain region DR. The p⁻-type region PR is arranged in the convex portion CON.

The p⁻-type region PR has the same p-type impurity concentration as the p⁻-type substrate region SBR. In addition, the p⁻-type region PR has a lower p-type impurity concentration than the p-type RESURF region RS. An upper end of the p⁻-type region PR forms a pn junction with the n⁺-type drain region DR. A lower end of the p⁻-type region PR is connected to the p-type RESURF region RS.

Note that the configuration other than those described above in the present embodiment is substantially the same as that of the first embodiment shown in FIG. 2. Therefore, the same elements are denoted by the same reference sign, and redundant descriptions thereof are omitted as appropriate.

<Method Of Manufacturing The LDMOS Transistor>

Next, the manufacturing method of the LDMOS transistor as the semiconductor device according to the present embodiment will be described with reference to FIGS. 15 to 17.

First, the manufacturing method of the present embodiment undergoes similar steps as the steps in the first embodiment shown in FIG. 4. Subsequently, as shown in FIG. 15, the n-type well region DF is selectively formed in the semiconductor substrate SB. Subsequently, the p-type RESURF region RS is formed in the semiconductor substrate SB. The p-type RESURF region RS is formed so as to be in contact with the side portion of the n-type well region DF. In addition, the p-type RESURF region RS is formed at a predetermined depth away from the surface SU of the semiconductor substrate SB. For this reason, the p⁻-type region PR is located between the p-type RESURF region RS and the surface SU of the semiconductor substrate SB. The p⁻-type region PR is originally a portion of the p⁻-type substrate region SBR. For this reason, the p⁻-type region PR has the same p-type impurity concentration as the p⁻-type substrate region SBR.

Next, as shown in FIG. 16, a mask layer MK3 made of, for example, a silicon oxide film is formed on the surface of the semiconductor substrate SB. Anisotropic wet etching using, for example, the TMAH aqueous solution is performed with the mask layer MK3 serving as a mask. This etching allows the surface of the semiconductor substrate SB exposed from the mask layer MK3 to be selectively removed.

In this anisotropic wet etching, there is a large crystal orientation dependence, and in the case of silicon, the etching rate is fast in the <100> direction and is the slowest in the <111> direction. For this reason, performing anisotropic wet etching using a silicon substrate with a (100) plane allows the convex portion CON having the side surfaces SS1 and SS2 with a (111) plane to be formed. Thus, the trapezoidal convex portion CON having the side surfaces SS1 and SS2 inclined with respect to the surface SU of the semiconductor substrate SB, and the upper surface US connecting each of the upper ends of the side surfaces SS1 and SS2 is formed. In addition, the convex portion CN having the side surface SS3 with a (111) plane is also formed by the above-described anisotropic wet etching.

The above-described etching makes it possible to distinguish between the first semiconductor region DF1 located below the convex portion CON and the second semiconductor region DF2 located in the convex portion CON with respect to the surface SU of the semiconductor substrate SB. In other words, the n-type drift region DF can be divided into the first semiconductor region DF1 located below the surface SU of the semiconductor substrate SB and the second semiconductor region DF2 located above the surface SU of the semiconductor substrate SB. Subsequently, the mask layer MK3 is removed.

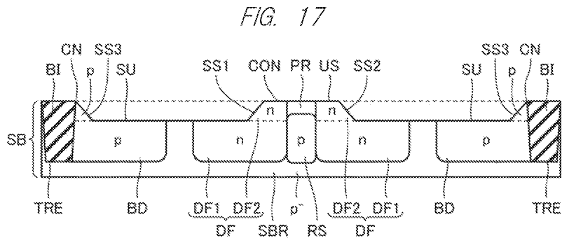

Next, as shown in FIG. 17, the p-type diffusion region BD is selectively formed in the surface SU of the semiconductor substrate SB. The p-type diffusion region BD is the p-type body region. When forming the p-type diffusion region BD, p-type impurities are selectively ion-implanted into the semiconductor substrate SB. At this time, p-type impurities are also implanted into the convex portion CN. For this reason, a p-type diffusion region is also formed in a region of the convex portion CN where the STI structure is not formed.

Subsequently, the manufacturing method of the present embodiment undergoes the same steps as the manufacturing method of the first embodiment. Thus, the LDMOS transistor TR of the present embodiment shown in FIG. 14 is formed.

<Effects>

According to the present embodiment, the p-type RESURF region RS having a higher p-type impurity concentration than the p⁻-type substrate region SBR forms a pn junction with the side portion of each of the first semiconductor region DF1 and the second semiconductor region DF2 as shown in FIG. 14. Thus, a more pronounced RESURF effect can be obtained.

In addition, since a more pronounced RESURF effect can be obtained by the p-type RESURF region RS, a high breakdown voltage can be obtained even if the n-type impurity concentration in the n-type drift region DF is increased. Thus, the ON resistance can be reduced since the n-type impurity concentration in the n-type drift region DF can be increased.

In addition, the p-type RESURF region RS is arranged at a position away from the n⁺-type drain region DR. Thus, it is possible to avoid a connection between the n⁺-type drain region DR having a high concentration and the p-type RESURF region RS.

<Application Example>

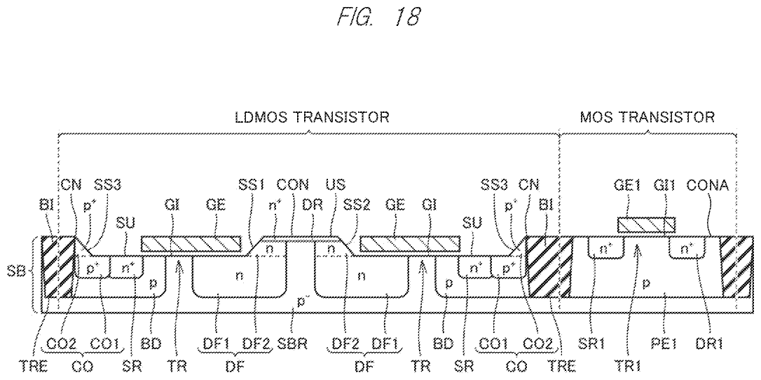

Next, an example of applying the semiconductor device according to the present embodiment will be described with reference to FIG. 18.

As shown in FIG. 18, the LDMOS transistor TR of the present embodiment is arranged in the semiconductor substrate SB with, for example, a MOS transistor. In a formation region of the MOS transistor, a convex portion CONA is provided in the surface SU of the semiconductor substrate SB. A MOS transistor TR1 is arranged in the convex portion CONA. The MOS transistor TR1 has an n⁺-type source region SR1, an n⁺-type drain region DR1, a gate insulating layer GI1, and a gate electrode GE1.

In the formation region of the MOS transistor, a p-type region PE1 is arranged in the convex portion CONA. The n⁺-type source region SR1 and the n⁺-type drain region DRi are arranged in an upper surface of the convex portion CONA. The n⁺-type source region SR1 and the n⁺-type drain region DR1 each form a pn junction with the p-type region PE1.

The gate electrode GE1 is arranged on the upper surface of the convex portion CONA with the gate insulating layer GI1 interposed therebetween. The gate electrode GE1 is arranged on a region sandwiched between the n⁺-type source region SR1 and the n⁺-type drain region DR1.

A height of the convex portion CONA from the surface SU of the semiconductor substrate SB is the same as that of the convex portion CON from the surface SU of the semiconductor substrate SB. For this reason, the upper end of each of the n⁺-type source region SR1 and the n⁺-type drain region DR1 of the MOS transistor is located at the same height as the upper end of the n⁺-type drain region DR of the LDMOS transistor TR. In addition, the gate electrode GE1 of the MOS transistor TR1 is arranged at a higher position than the gate electrode GE of the LDMOS transistor TR.

In this manner, the LDMOS transistor TR of the present embodiment may be arranged together with a MOS transistor. In addition, the LDMOS transistor TR may be arranged together with other elements.

In FIGS. 2, 3, 9 and 14, configurations in which the lower end of the n-type drift region DF is in contact with the p⁻-type substrate region SBR has been described. However, an additional p-type RESURF region in contact with the lower end of the n-type drift region DF may be provided. This additional p-type RESURF region has a higher p-type impurity concentration than the p⁻-type substrate region SBR. In addition, the additional p-type RESURF region is located between the p⁻-type substrate region SBR and the n-type drift region DF and forms a pn junction with the n-type drift region DF by coming in contact with the lower end of the n-type drift region DF. The additional p-type RESURF region in contact with the lower end of the n-type drift region DF provides a more pronounced RESURF effect.

In the foregoing, the invention made by the present inventors has been concretely described based on the embodiments. However, it is needless to say that the present invention is not limited to the foregoing embodiments, and various modifications and alterations can be made within the scope of the present invention.

What is claimed is:

1. A semiconductor device comprising:
a semiconductor substrate having a surface, and a convex portion projecting upward from the surface;
a gate electrode arranged on the surface of the semiconductor substrate;
a first region of a first conductivity type having a portion located in the convex portion; and
a drain region of the first conductivity type, the drain region having a higher impurity concentration than the first region and being arranged in the convex portion and on the first region such that the drain region and the gate electrode sandwich the first region in plan view.

2. The semiconductor device according to claim 1,
wherein the first region includes:
a first semiconductor region arranged below the convex portion, and
a second semiconductor region arranged in the convex portion, and
wherein an impurity concentration of the second semiconductor region of the first conductivity type is equal to an impurity concentration of the first semiconductor region of the first conductivity type.

3. The semiconductor device according to claim 2, comprising:
a second region of a second conductivity type adjacent to each of the first semiconductor region and the second semiconductor region.

4. The semiconductor device according to claim 3,
wherein the second region has a portion arranged in the convex portion.

5. The semiconductor device according to claim 3,
wherein the second region is electrically connected to a ground potential.

6. The semiconductor device according to claim 1,
wherein a side surface of the convex portion is inclined with respect to the surface of the semiconductor substrate.

7. The semiconductor device according to claim 1,
wherein a side surface of the convex portion is arranged upright so as to be orthogonal to the surface of the semiconductor substrate.

8. The semiconductor device according to claim 1,
wherein a side surface of the convex portion is configured by an inclined surface of a {111} plane.

9. The semiconductor device according to claim 3,
wherein the second region includes:
a substrate region, and
a high-concentration region having a higher impurity concentration of the second conductivity type than the substrate region, and
wherein the substrate region is adjacent to a lower end of the first region, and the high-concentration region is adjacent to a side portion of the first region.

10. The semiconductor device according to claim 9,
wherein the high-concentration region is arranged away from the drain region.

11. The semiconductor device according to claim 1, comprising:
a second transistor that differs from a first transistor having the drain region and the gate electrode,
wherein an upper end of each of a source region of the second transistor and a drain region of the second transistor is arranged at the same height as an upper end of the drain region of the first transistor.

12. A semiconductor device comprising:
a semiconductor substrate having a surface, and a first convex portion and a second convex portion each projecting upward from the surface;
a first transistor having a first source region arranged in the surface, and a first drain region arranged in the first convex portion; and
a second transistor having a second source region and a second drain region arranged in the second convex portion.

13. A method of manufacturing a semiconductor device comprising:
forming a semiconductor substrate having a surface, a convex portion projecting upward from the surface, and a first region of a first conductivity type arranged in the convex portion;
forming a gate electrode on the surface of the semiconductor substrate; and
forming a drain region of the first conductivity type, the drain region having a higher impurity concentration than the first region and being arranged in the convex portion and on the first region such that the drain region and the gate electrode sandwich the first region in plan view.
